(19) United States
(12) Patent Application Publication
(10) Pub. No.: US 2026/0100329 A1
(43) Pub. Date: Apr. 9, 2026

(54) COMBINED THERMAL AND PLASMA ASSISTED ATOMIC LAYER DEPOSITION

(71) Applicant: Applied Materials, Inc., Santa Clara, CA (US)

(72) Inventors: Andrew Nguyen, Gilbert, AZ (US); Shankar Swaminathan, Chandler, AZ (US); Mohith Verghese, Phoenix, AZ (US); Kunal Bhatnagar, Chandler, AZ (US); Sue-Ann Yow, Mesa, AZ (US); Chau T. Nguyen, San Jose, CA (US); Sathya Swaroop Ganta, Sunnyvale, CA (US)

(73) Assignee: Applied Materials, Inc., Santa Clara, CA (US)

(21) Appl. No.: 18/909,487

(22) Filed: Oct. 8, 2024

(51) Int. Cl. H01J 37/32; H01L 21/311; H01L 21/67

(52) U.S. Cl. CPC H01J 37/3211; H10P 50/283; H01J 2237/334; H10P 72/0421

(57) ABSTRACT

A plasma coil assembly including a ring-shaped body, an RF electrode positioned within the ring-shaped body, and a dielectric top plate positioned within the ring-shaped body. A semiconductor manufacturing processing chamber including a processing chamber body, a gas distribution assembly, a substrate support, and the plasma coil assembly. A method of selectively etching a substrate surface including forming a process gas, exposing the substrate surface to the process gas to form activated fluorine-containing species, and sublimating the activated fluorine-containing species. A method of etching a substrate surface including exposing the substrate surface to a fluorine-containing plasma and applying a bias voltage to the substrate surface, the fluorine-containing plasma generated by the plasma coil assembly. A method of etching a substrate surface including exposing the substrate surface to an inductively coupled plasma and applying a bias voltage to the substrate surface, the inductively coupled plasma generated by the plasma coil assembly.

### TECHNICAL FIELD

Embodiments of the disclosure generally relate to electronic devices and methods of forming electronic devices. In particular, embodiments of the disclosure relate to a semiconductor manufacturing processing chamber comprising a plasma coil assembly. Embodiments of the disclosure also relate to methods of selectively etching substrate surfaces, including using the plasma coil assembly.

### BACKGROUND

The semiconductor processing industry continues to strive for larger production yields while increasing the uniformity of layers deposited on substrates having larger surface areas. These same factors in combination with new materials also provide higher integration of circuits per unit area of the substrate. As circuit integration increases, the need for greater uniformity and process control regarding layer thickness rises. As a result, various technologies have been developed to deposit layers on substrates in a cost-effective manner, while maintaining control over the characteristics of the layer.

The semiconductor industry faces many challenges in the pursuit of device miniaturization which involves rapid scaling of nanoscale features. Such issues include the introduction of complex fabrication steps such as multiple lithography steps and integration of high-performance materials. To maintain the cadence of device miniaturization, selective deposition has shown promise as it has the potential to remove costly lithographic steps by simplifying integration schemes.

Selective deposition of materials can be accomplished in a variety of ways. Process parameters such as pressure, substrate temperature, precursor partial pressures, and/or gas flows might be modulated to modulate the chemical kinetics of a particular surface reaction. Another possible scheme involves selective etching during the selective deposition to improve the quality of the deposited film and increase the selectivity of the deposition. Thus, there is an ongoing need for new processing chambers and methods that can accomplish selective etching, including as part of selective deposition.

### SUMMARY

Embodiments of the present disclosure relate to a plasma coil assembly. Embodiments of the present disclosure also relate to a semiconductor manufacturing processing chamber. Embodiments of the present disclosure also relate to a method of selectively etching a substrate surface. Embodiments of the present disclosure also relate to a method of etching a substrate surface using a fluorine-containing plasma. Embodiments of the present disclosure also relate to a method of etching a substrate surface using a plasma.

In some aspects, the techniques described herein relate to a plasma coil assembly including: a ring-shaped body having an inner wall with an inside face and an outside face, a bottom wall with an inside face and an outside face, and an outer wall with an inside face and an outside face, the ring-shaped body having an open top portion; an RF electrode positioned within the open top portion of the ring-shaped body, the RF electrode having a first end and a second end defining a length of the RF electrode, a thickness and a width, the RF electrode formed in a coil having at least two spaced revolutions with the first end spaced a distance from the outer wall of the ring-shaped body and the second end spaced a distance from the inner wall of the ring-shaped body, the first end closer to a lowest point of the outside face of the bottom wall than the second end; a first RF electrode connection in electrical contact with the first end of the RF electrode; a second RF electrode connection in electrical contact with the second end of the RF electrode; and a dielectric top plate positioned within the open top portion of the ring-shaped body.

In some aspects, the techniques described herein relate to a method of selectively etching a substrate surface, the method including: forming a process gas including fluorine-containing species; exposing the substrate surface to the process gas to form activated fluorine-containing species on the substrate surface, the substrate surface including an oxide or a nitride; and heating the substrate surface to sublimate the activated fluorine-containing species from the substrate surface, the heating being performed at least in part by an inductively coupled plasma (ICP) generated by a plasma coil assembly, the ICP including argon (Ar) or helium (He), the plasma coil assembly including: a ring-shaped body having an inner wall with an inside face and an outside face, a bottom wall with an inside face and an outside face, and an outer wall with an inside face and an outside face, the ring-shaped body having an open top portion; an RF electrode positioned within the open top portion of the ring-shaped body, the RF electrode having a first end and a second end defining a length of the RF electrode, a thickness and a width, the RF electrode formed in a coil having at least two spaced revolutions with the first end spaced a distance from the outer wall of the ring-shaped body and the second end spaced a distance from the inner wall of the ring-shaped body, the first end closer to a lowest point of the outside face of the bottom wall than the second end; a first RF electrode connection in electrical contact with the first end of the RF electrode; a second RF electrode connection in electrical contact with the second end of the RF electrode; and a dielectric top plate positioned within the open top portion of the ring-shaped body.

In some aspects, the techniques described herein relate to a method of etching a substrate surface, the method including: exposing the substrate surface to an inductively coupled plasma (ICP), the ICP including helium (He); and applying a bias voltage to the substrate surface, the ICP being generated at least in part by a plasma coil assembly including: a ring-shaped body having an inner wall with an inside face and an outside face, a bottom wall with an inside face and an outside face, and an outer wall with an inside face and an outside face, the ring-shaped body having an open top portion; an RF electrode positioned within the open top portion of the ring-shaped body, the RF electrode having a first end and a second end defining a length of the RF electrode, a thickness and a width, the RF electrode formed in a coil having at least two spaced revolutions with the first end spaced a distance from the outer wall of the ring-shaped body and the second end spaced a distance from the inner wall of the ring-shaped body, the first end closer to a lowest point of the outside face of the bottom wall than the second end; a first RF electrode connection in electrical contact with the first end of the RF electrode; a second RF electrode connection in electrical contact with the second end of the RF electrode; and a dielectric top plate positioned within the open top portion of the ring-shaped body.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a semiconductor manufacturing processing chamber according to some embodiments of the present disclosure;

FIG. 2 illustrates a semiconductor manufacturing processing chamber according to some embodiments;

FIG. 3 illustrates a plasma coil assembly according to some embodiments;

FIG. 4 illustrates an RF electrode according to some embodiments;

FIGS. 5A-5B illustrate an RF electrode according to some embodiments;

FIG. 6A illustrates a side view of an RF electrode according to some embodiments;

FIGS. 6B-6E schematically illustrate different arrangements of the RF electrode shown in FIG. 6A according to some embodiments;

FIG. 7A illustrates an RF electrode with a circular cross-section according to one or more embodiment of the disclosure; and

FIG. 7B illustrates an RF electrode with a rectangular cross-section according to one or more embodiment of the disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” or “wafer” refers to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

“Atomic layer deposition” or “cyclical deposition” as used herein refers to a process comprising the sequential exposure of two or more reactive compounds to deposit a layer of material on a substrate surface. “Atomic layer deposition” or “cyclical deposition” as used herein refers to a process comprising the sequential exposure of two or more reactive compounds to deposit a layer of material on a substrate surface. The substrate, or portion of the substrate, is exposed separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

In an embodiment of a spatial ALD process, a first reactive gas and second reactive gas (e.g., nitrogen gas) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas. The gas curtain can be any suitable gas separation arrangement known to the skilled artisan. For example, in some embodiments of a spatial ALD process chamber, a gas curtain is formed by a combination of purge gas ports and vacuum ports to maintain separation between the reactive gases to prevent gas-phase reactions. In some embodiments of a spatial ALD process chamber, separate process stations are configured to form a mini-process environment within each station.

As used in this specification and the appended claims, the terms “reactive compound”, “reactive gas”, “reactive species”, “precursor”, “process gas” and the like are used interchangeably to mean a substance with a species capable of reacting with the substrate surface or material on the substrate surface in a surface reaction (e.g., chemisorption, oxidation, reduction, cycloaddition). The substrate, or portion of the substrate, is exposed sequentially to the two or more reactive compounds which are introduced into a reaction zone of a processing chamber.

The term “about” as used herein means approximately or nearly and in the context of a numerical value or range set forth means a variation of ±15% or less, of the numerical value. For example, a value differing by ±14%, ±10%, ±5%, ±2%, ±1%, ±0.5%, or ±0.1% would satisfy the definition of “about.”

Spatially relative terms, such as “beneath,” “below,” “lower,” “above,” “upper” and the like, may be used herein for ease of description to describe one element or feature's relationship to another element(s) or feature(s) as illustrated in the Figures. It will be understood that the spatially relative terms are intended to encompass different orientations of a device in use or operation in addition to the orientation depicted in the figures. For example, if the device in the Figures is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

As used in this specification and the appended claims, the term “selectively” refers to a process which acts on a first surface with a greater effect than another second surface. Such a process would be described as acting “selectively” on the first surface over the second surface. The term “over” used in this regard does not imply a physical orientation of one surface on top of another surface, rather a relationship of the thermodynamic or kinetic properties of the chemical reaction with one surface relative to the other surface.

As used herein, the phrase “selectively over,” or similar phrases, means that the subject material is deposited on the stated surface to a greater extent than on another surface. In some embodiments, “selectively” means that the subject material forms on the selective surface at a rate greater than or equal to about 10×, 15×, 20×, 25×, 30×, 35×, 40×, 45× or 50× the rate of formation on the non-selected surface. In some embodiments, the passivation layer forms on the selective and does not form on the non-selective surface with a selectivity ratio of at least about 10:1, or at least about 100:1, or at least about 1000:1.

The term “on” indicates that there is direct contact between elements. The term “directly on” indicates that there is direct contact between elements with no intervening elements.

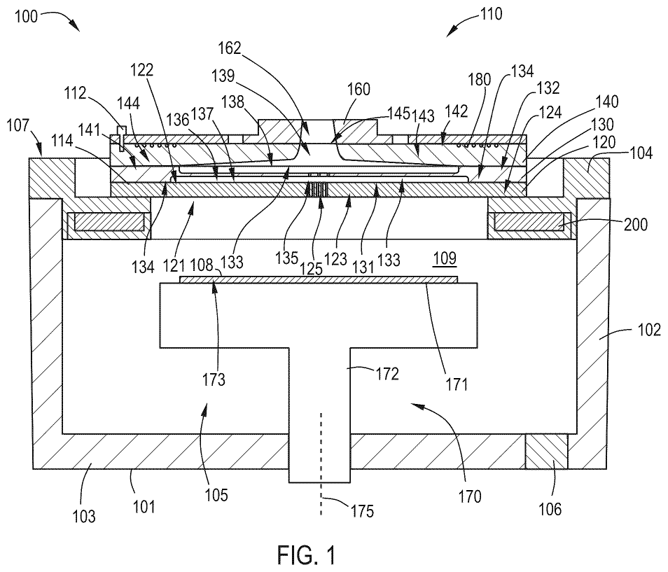

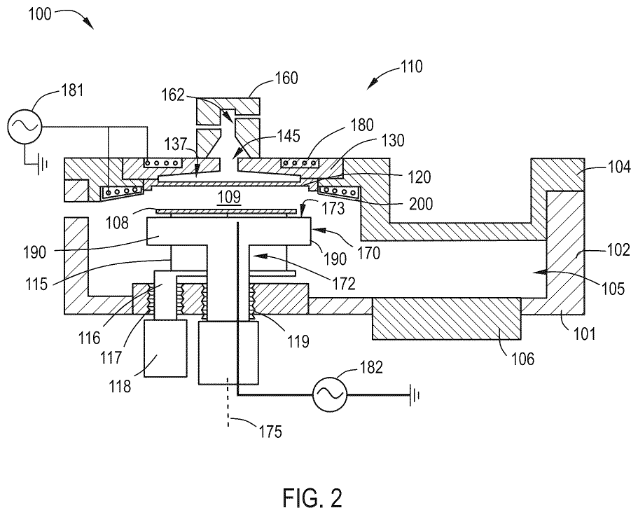

FIG. 1 and FIG. 2 illustrate a semiconductor manufacturing processing chamber 100 according to some embodiments of the present disclosure. The semiconductor manufacturing processing chamber 100 comprises a chamber body 101 having sidewalls 102 and a bottom wall 103 surrounding an interior volume 105. The sidewall 102 and the bottom wall 103 can be integrally formed or separate components connected together by any suitable connection or fastener known to the skilled artisan. In the embodiment illustrated in FIG. 1, the sidewall 102 and bottom wall 103 are integrally formed.

In some embodiments, the chamber body 101 includes a chamber lid 104. The chamber lid 104 can be permanently connected to the sidewall 102, or a separate component that is attached to the sidewall 102 by any suitable connection known to the skilled artisan. For example, in some embodiments, the chamber lid 104 is fastened to the sidewall 102 of the chamber body 101 using a removable fastener (e.g., a bolt) with a suitable sealing element (e.g., an O-ring) to isolate the interior volume 105 from the external environment.

The semiconductor manufacturing processing chamber 100 of some embodiments includes a gas distribution assembly 110. In some embodiments, as shown in FIG. 1, the gas distribution assembly 110 comprises a faceplate 120 (also referred to as a showerhead), a backing plate 130 and a thermal base 140. In some embodiments, such as the embodiment illustrated schematically in FIG. 2, the gas distribution assembly 110 has two components, a faceplate 120 and a backing plate 130, as will be understood by the skilled artisan.

The chamber body 101, in conjunction with the chamber lid 104 (which may include gas distribution assembly 110) encloses the interior volume 105 of the semiconductor manufacturing processing chamber 100. During processing, the interior volume 105 of the semiconductor manufacturing processing chamber 100 is typically maintained at a controlled pressure (usually a low-pressure environment) using one or more gas inlet (not shown) and one or more exhaust 106. The exhaust 106 is illustrated as part of the bottom wall 103. However, the skilled artisan will recognize that the exhaust 106 can be located in any suitable location and configuration. The skilled artisan will be familiar with the general construction of the chamber body 101 and the use of gas inlets and exhaust systems.

In some embodiments, the gas distribution assembly 110 is considered part of the chamber lid 104 and is either integrally formed with the chamber lid 104 or connected to the chamber lid 104 using any suitable fastener known to the skilled artisan. In the embodiment illustrated in FIG. 1, the gas distribution assembly 110 comprises multiple plates connected to the top surface 107 of the chamber lid 104 using a fastener 112 with O-rings 114. In the illustrated embodiment, there are at least one O-ring 114 between each of the chamber lid 104 and faceplate 120, between the faceplate 120 and the backing plate 130, and between the backing plate 130 and the thermal base 140. Although a single fastener 112 is illustrated connecting the thermal base 140, backing plate 130 and faceplate 120 to the chamber lid 104, the skilled artisan will recognize that there can be more than one fastener, with each faster connecting less than all of the components to the adjacent component. For example, in some embodiments, a first fastener connects the faceplate 120 to the chamber lid 104, a second fastener connects the backing plate 130 to the faceplate 120, and a third fastener connects the thermal base 140 to the backing plate 130.

The faceplate 120 has a front surface 121 and a back surface 122 defining a thickness of the faceplate 120. The faceplate 120 has an inner portion 123 and an outer portion 124. The inner portion 123 of the faceplate 120 comprises a plurality of apertures 125 extending though the thickness of the faceplate 120. The outer portion 124 of the faceplate, in some embodiments, is defined as the region outside of the plurality of apertures 125. In some embodiments, the outer portion 124 of the faceplate is defined as the portion of the back surface 122 of the faceplate 120 that is in contact with the front surface 131 of the backing plate 130.

The backing plate 130 has a front surface 131 and a back surface 132 that define a thickness of the backing plate 130. The backing plate 130 has an inner portion 133 and an outer portion 134. The outer portion 134 of the backing plate 130 contacts the back surface 122 of the faceplate 120. The inner portion 133 of the backing plate 130 comprises a plurality of apertures 135 extending through the thickness of the backing plate 130. The inner portion 133 of the backing plate 130 aligns with the inner portion 123 of the faceplate 120 and the outer portion 134 of the backing plate 130 aligns with the outer portion 124 of the faceplate 120.

In the illustrated embodiment of FIG. 1, the backing plate 130 has a front recess 136 in the front surface 131 of the backing plate 130. The front recess 136 creates a plenum 137 between the front surface 131 of the backing plate 130 and the back surface 122 of the faceplate 120. The skilled artisan will recognize that the plenum 137 can be formed between the faceplate 120 and the backing plate 130 without the front recess 136 in the front surface 131 of the backing plate 130. For example, in some embodiments, the inner portion 123 of the faceplate 120 is recessed below the outer portion 124 of the faceplate 120 to create a recessed area in the back surface 122 of the faceplate 120 and the front surface 131 of the backing plate 130 does not include a recess. In this arrangement, a plenum 137 exists between the faceplate 120 and the backing plate 130.

In the illustrated embodiment of FIG. 1, the back surface 132 of the backing plate 130 includes a back recess 138 in the inner portion 133 of the backing plate 130. The back recess 138 can form a plenum 139 with the front surface 141 of the thermal base 140. However, the skilled artisan will recognize that the back surface 132 of the backing plate 130 can be flat (i.e., without the back recess 138) and still form the plenum 139 with the thermal base 140.

The thermal base 140 has a front surface 141 and a back surface 142 defining a thickness of the thermal base 140. The thermal base 140 includes an inner portion 143 and an outer portion 144. The thermal base 140 has an inlet opening 145 in a center thereof. The inlet opening 145 extends through the thickness of the thermal base 140 from the back surface 142 to the front surface 141. The central axis of the thermal base 140 is defined at the center of the inlet opening 145. The outer peripheral edge of the inner portion 143 of the front surface 141 is concentric with the inlet opening 145. While the thermal base 140 of some embodiments has an oblong or non-symmetrical shape, the central axis is considered to be at the center of the inlet opening 145 even if that is not the center of mass of the thermal base 140.

In some embodiments, the front surface 141 of the thermal base 140 at the inner portion 143 has a concave shape or profile. The concave shape or profile of some embodiments has a linear slope from the inlet opening 145 to the outer peripheral edge of the inner portion 143 at the transition to the outer portion 144. In some embodiments, as shown in FIG. 1, the concave shape has a curved profile from the inlet opening 145 to the outer peripheral edge of the inner portion 143. In some embodiments, the plenum 139 is formed between the curved profile or concave shape of the inner portion 143 of the front surface 141 of the thermal base 140 and the back surface 132 of the backing plate 130, or as illustrated, between the inner portion 143 of the front surface 141 of the thermal base 140 and the back recess 138 of the back surface 132 of the backing plate 130.

The thermal base 140 in the illustrated embodiment is in contact with the backing plate 130 and can be connected to the backing plate 130 by any suitable connection known to the skilled artisan. For example, the thermal base 140 can be welded to the backing plate 130. In some embodiments, as illustrated in FIG. 1, the thermal base 140 is connected to the backing plate 130 with a plurality of fasteners. Suitable fasteners include, but are not limited to, bolts, and can be used with or without O-rings.

In some embodiments, the plenum 137 and/or plenum 139 has a coating to improve chemical compatibility. The skilled artisan will understand that the coating on the plenum is actually a coating on the portions of the gas distribution assembly 110 that form the plenum. In some embodiments, the coating covers the entire front surface 131 of the backing plate 130 and the entire back surface 122 of the faceplate 120, including in the plurality of apertures 125 of the faceplate 120 and the plurality of aperture 135 of the backing plate 130. In some embodiments, the coating is only on the portions of the backing plate 130 and faceplate 120 that will come into contact with the process gases. The skilled artisan will also recognize that the coating can be on the front surface 141 of the thermal base 140 and the back surface 132 of the backing plate 130 to improve chemical compatibility in the plenum 139.

In some embodiments, the gas distribution assembly 110 has two components, rather than the illustrated three components. For example, the gas distribution assembly 110 of some embodiments has a faceplate 120 and a thermal base 140 without a backing plate 130 to separate the two.

In some embodiments, the gas distribution assembly 110 further comprises a cap housing 160 connected to the back surface 142 of the thermal base 140. The cap housing 160 has an opening 162 aligned with the inlet opening 145 of the thermal base 140.

Referring to FIG. 1, the semiconductor manufacturing processing chamber 100 comprises a substrate support 170 within the interior volume 105. The substrate support 170 of some embodiments comprises a support body 171 positioned on a support shaft 172. The support body 171 has a support surface 173 configured to support a semiconductor wafer 108 for processing. Referring to FIG. 2, in some embodiments, the wafer 108 can be supported by one or more wafer lift pins 115 for lifting the wafer 108 above the support surface 173. In some embodiments, the wafer lift pins are supported by a wafer lift hoop 116, wafer lift bellows 117 for maintaining a pressure inside the interior volume 105, and an indexer 118.

The support shaft 172 of some embodiments is configured to move the support body 171 (also referred to as a substrate support) closer to or further from the faceplate 120 and/or around a rotational axis 175 of the support shaft 172. Stated differently, in some embodiments, the support shaft 172 is configured to move the substrate support to adjust a distance between the support surface and the lid of the processing chamber body. During processing, the support surface 173 is spaced from the front surface 121 of the faceplate 120 to form a process gap 109. The process gap 109 has a process height defined as a vertical distance between the front surface 121 of faceplate 120 and the support surface 173. While not shown, the skilled artisan will understand that rotational and translational movement of the substrate support 170 can be driven by any suitable mechanism including, but not limited to, motors and actuators.

In some embodiments, the support body 171 includes a thermal element (not shown) configured to heat the semiconductor wafer 108 on the support surface 173. The thermal element can be any suitable heating mechanism known to the skilled artisan. For example, in some embodiments, the thermal element comprises a resistive heating element that is connected to a power supply (not shown) configured to apply power to the thermal element to heat the support body 171. In some embodiments, the support body 171 comprises a cathode (not shown). Referring to FIG. 2, in some embodiments, the support body 171 includes an electrostatic chuck (ESC) 190. The ESC in some embodiments comprises a thermal element configured to heat the ESC to an elevated temperature. The ESC in some embodiments is supported by a bellow 119 for maintaining a pressure in the interior volume 105 when the support shaft is moved vertically during semiconductor device manufacturing. The skilled artisan will be familiar with the construction of the ESC 190 and the manner in which the ESC 190 is powered and employed.

In some embodiments, as shown in FIG. 1, the support surface 173 comprises more than one component. For example, the illustrated embodiment has two components connected together by any suitable connection (e.g., brazing or welding). Use of multiple components may allow for easier assembly of the thermal elements or electrostatic chuck components which can be enclosed by the support body components.

In some embodiments, the semiconductor manufacturing processing chamber 100 includes a plasma coil assembly 200 located within the interior volume 105 of the semiconductor manufacturing processing chamber 100. In some embodiments, the semiconductor manufacturing processing chamber 100 includes secondary RF coils 180. The secondary RF coils RF of some embodiments are operably connected to a source RF 181. In some embodiments, the semiconductor manufacturing processing chamber 100 includes a bias RF 182 operably connected to the ESC 190.

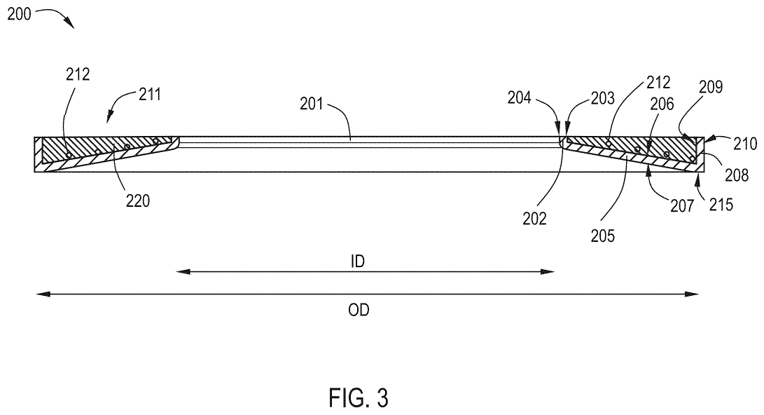

FIG. 3 illustrates a cross-sectional view of a plasma coil assembly 200 according to one or more embodiment of the disclosure. In some embodiments, the ICP coil assembly 200 is a ring or annulus positioned above the support body 171. In some embodiments, the inner diameter of the plasma coil assembly 200 is greater than the diameter of the support body 171, or greater than the diameter of the wafer 108. In some embodiments, the plasma coil assembly 200 is configured to excite a plasma gas in the process gap 109 in contact with the wafer 108. In some embodiments, the plasma is an inductively coupled plasma. The plasma gas may be introduced into the process gap 109 from the plurality of apertures 125 of the faceplate 120.

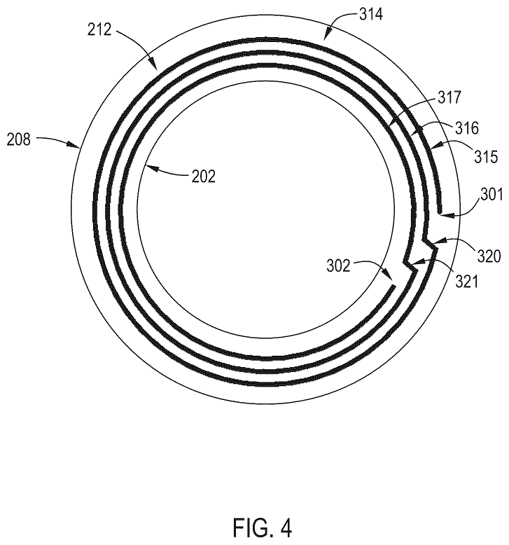

With reference to FIGS. 1 and 4, in some embodiments, the ICP coil assembly 200 has a ring-shaped body 201 having an inner wall 202 with an inside face 203 and an outside face 204. In some embodiments, the ICP coil assembly 200 has a bottom wall 205 with an inside face 206 and an outside face 207. In some embodiments, the ICP coil assembly 200 has an outer wall 208 with an inside face 209 and an outside face 210. The ICP coil assembly 200 of some embodiments has an open top portion 211, as illustrated schematically in FIG. 3. In some embodiments, the ICP coil assembly 200 comprises an RF electrode 212 positioned within the open top portion 211 of the ring-shaped body 201.

The ring-shaped body 201 can be made of any suitable material. In some embodiments, the ring-shaped body 201 is made of a conductive material. In some embodiments, the ring-shaped body 201 is made of an insulating material (e.g., a dielectric material).

In some embodiments, the ring-shaped body 201 has an inner diameter ID measured from the outside face 204 of the inner wall 202. The inner diameter ID of some embodiments is in a range of 250 mm to 500 mm. In some embodiments, ID is about 300 mm. In some embodiments, the ring-shaped body 201 has an outer diameter OD measured from the outside face 210 of the outer wall 208. The outer diameter OD of some embodiments is in a range of from 450 mm to 650 mm. In some embodiments, OD is about 550 mm. In some embodiments, ID is less than OD, ID is in a range of from 250 mm to 500 mm, and OD is in a range of from 450 mm to 650 mm.

In some embodiments, the plasma coil assembly 200 has a dielectric top plate 220 positioned within the open top portion 211 of the ring-shaped body. The dielectric top plate 220 can be made of any suitable dielectric material known to the skilled artisan. In some embodiments, the dielectric top plate 220 comprises a ceramic material. In some embodiments, the ceramic material comprises aluminum oxide (Al₂O₃) or aluminum nitride (AlN). In some embodiments, the dielectric top plate 220 and the ring-shaped body 201 are bonded.

The RF electrode 212 of the ICP coil assembly 200 can have any suitable shape within the ring-shaped body 201. FIG. 4 illustrates a top view of a RF electrode 212 according to one or more embodiments of the disclosure. In some embodiments, the RF electrode 212 has a first end 301 and a second end 302, the first end 301 and the second end 302 defining a length of RF electrode 212. The first end 301 may be spaced a distance from the outer wall 208 of the ring-shaped body 201, and the second end 302 may be spaced a distance from the inner wall 202 of the ring-shaped body 201. Stated differently, in some embodiments, the first end 301 of the RF electrode 212 is spaced a distance from the inside face 209 of the outer wall 208, and the second end 302 is spaced a distance from the inside face 206 of the inner wall 202. In some embodiments, the first end 301 is spaced a distance greater than or equal to 0.1 inches from the inside face 209 of the outer wall 208 and the second end 302 is spaced a distance greater than or equal to 0.1 inches from the inside face 206 of the inner wall 202. In some embodiments, the first end 301 is spaced a distance less than or equal to 0.3 inches from the inside face 209 of the outer wall 208 and the second end 302 is spaced a distance less than or equal to 0.3 inches from the inside face 206 of the inner wall 202.

In some embodiments, the RF electrode 212 is formed in the shape of a spiral coil 314, the spiral coil 314 having least two spaced revolutions 315 and 316. In some embodiments, as illustrated in FIG. 4, the spiral coil 314 has three spaced revolutions, such as an outer revolution 315, a middle revolution 316, and an inner revolution 317. In some embodiments, two or more of the spaced revolutions are concentric. In some embodiments, a distance between adjacent spaced revolutions, such as between spaced revolutions 315 and 316, or between spaced revolutions 316 and 317, is in a range of from 0.1 inches to 3 inches. While three revolutions are illustrated in FIG. 4, the skilled artisan will understand that the disclosure is not limited to three revolutions. In some embodiments, the spiral coil 314 has greater than or equal to 2, 3, 4, 5, 6, 7, 8, 9 or 10 revolutions.

In some embodiments, as shown in FIG. 4, the outer spaced revolution 315 is connected to the middle spaced revolution 316 by an outer straight segment 320. In some embodiments, the middle spaced revolution 316 is connected to the inner spaced revolution 317 by an inner straight segment 321. In some embodiments, each of the spaced revolutions in the spiral coil 314, such as each of 315, 316, and 317, extend less than 355° allowing sufficient space for the straight segment connecting the coil revolution to the adjacent coil revolution.

Referring to FIG. 3, in some embodiments, the first end 301 of RF electrode 212 is spaced closer to a lowest point 215 of the bottom wall 205 as compared to the second end 302. FIG. 3 shows a RF electrode 212 with four revolutions in which the outermost revolution is spaced closer to a lowest point 215 of the bottom wall 205 compared to the innermost revolution. In some embodiments, going in the direction from an innermost spaced revolution to the outermost spaced revolution, each spaced revolution is spaced closer to the lowest point 215 as compared to the previous spaced revolution.

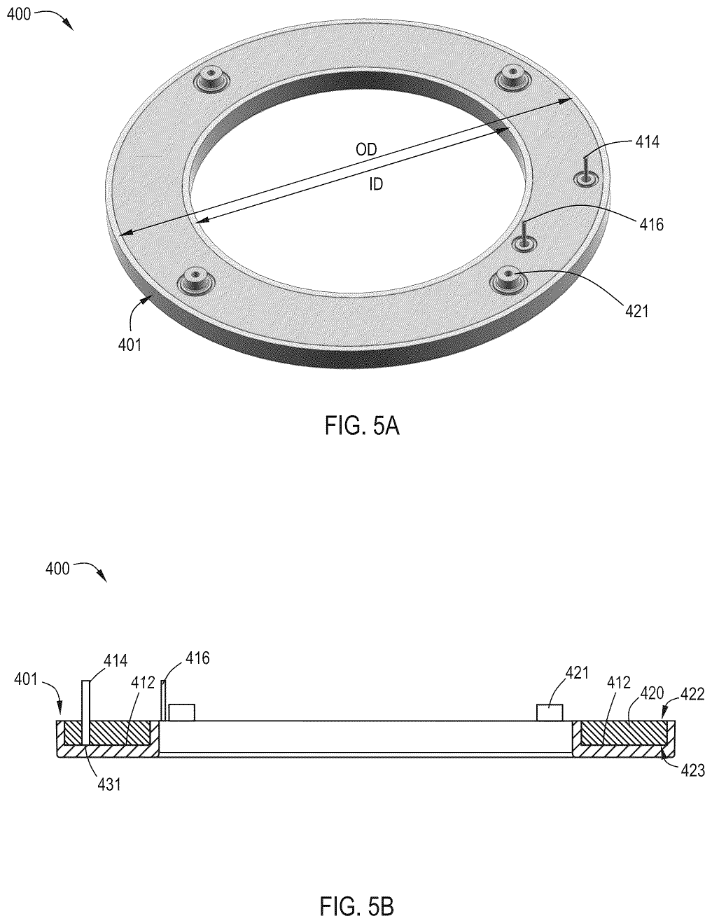

FIGS. 5A-5B illustrate orthographic and cross-sectional views, respectively, of a plasma coil assembly 400 according to some embodiments. The RF electrode 412 in plasma coil assembly 400 may have a first RF electrode connection 414, which may be in electrical connection with the first end 431 of the RF electrode 412. In some embodiments, the RF electrode 412 may have a second RF electrode connection 416, which may be in electrical connection with the second end of the RF electrode 412.

In some embodiments, the plasma coil assembly 400 includes the dielectric top plate 420. In some embodiments, the dielectric top plate 420 comprises a ceramic material. In some embodiments, the ceramic material comprises aluminum oxide (Al₂O₃) or aluminum nitride (AlN). In some embodiments, the dielectric top plate 420 has a top 422 and a bottom 423. In some embodiments, the top 422 comprises Al₂O₃. In some embodiments, the bottom 423 comprises Al₂O₃. In some embodiments, both the top 422 and bottom 423 of dielectric top plate 420 comprise the same material, such as Al₂O₃ or AlN. In some embodiments, the dielectric top plate 420 and the ring-shaped body 401 are bonded (e.g., with high electrical thermal paste or by sintering).

In some embodiments, the plasma coil assembly, such as plasma coil assembly 200, 400, or 500 as described herein, is removable from the semiconductor manufacturing processing chamber 100. In some embodiments, the RF electrode, such as RF electrode 412, is removable from the semiconductor processing chamber. In some embodiments, the dielectric top plate 420 is removable from the semiconductor processing chamber. In some embodiments, both the dielectric top plate 420 and the RF electrode 412 are removable form the semiconductor processing chamber. In some embodiments, the dielectric top plate 420 is mounted on the ring-shaped body 401 of plasma coil assembly 400 by a mounting, such as by a screw mounting 421.

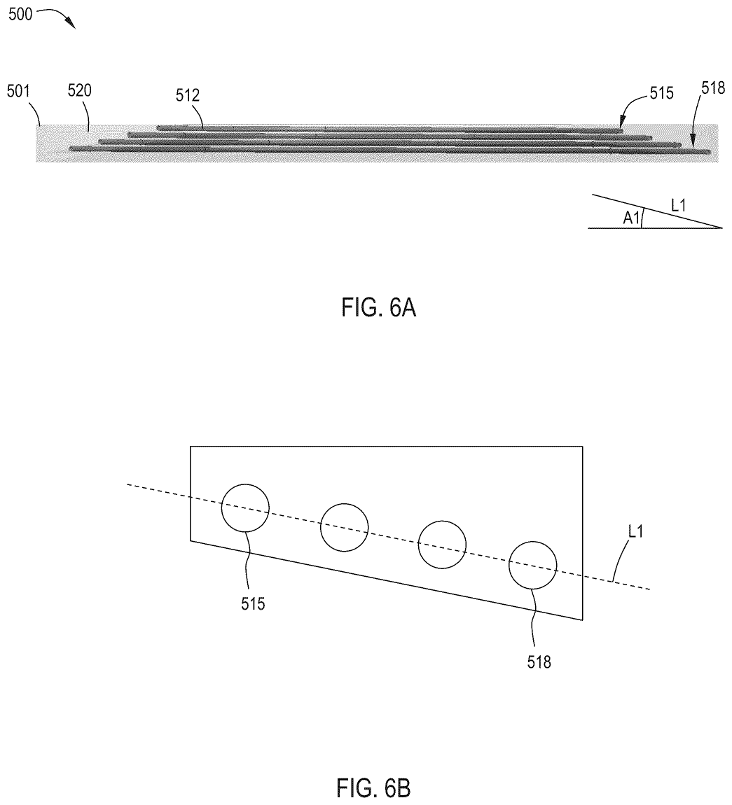

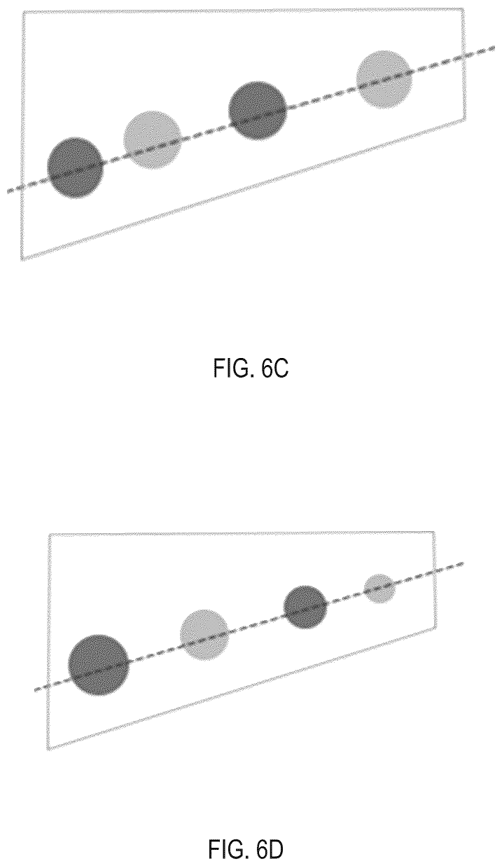

In some embodiments, the RF electrode, such as the RF electrode 212 as illustrated in FIG. 3, may be a frustoconical RF electrode as illustrated in FIG. 6A. FIG. 6A illustrates an ICP coil apparatus 500 having a ring-shaped body 501, a dielectric top plate 520 is positioned within the ring-shaped body 501, and a frustoconical RF electrode 512 housed within the ring-shaped body 501.

In some embodiments, the frustoconical RF electrode 512 has a top revolution 515 and a bottom revolution 518, as illustrated in FIG. 6A. The frustoconical RF electrode 512 illustrated in FIG. 6A is shown as having four revolutions; however, the number of revolutions is non-limiting. For example, the frustoconical RF electrode 512 may have a number of revolutions in a range anywhere from 2 revolutions to 8 revolutions.

In some embodiments, the top revolution 515 and the bottom revolution 518 are concentric. The frustoconical RF electrode may be defined using an angle A1. Angle A1 can be uniquely defined as being the angle formed by the following two lines: the vertical line passing through the concentric centers of top revolution 515 and bottom revolution 518, and any line which intersects the vertical line, the outer diameter of top revolution 515, and the outer diameter of bottom revolution 518. The angle A1 further defines a line L1, as illustrated schematically in FIG. 6A.

In some embodiments, the revolutions of the RF electrode 512 may be arranged such that each pair of spaced revolutions of the frustoconical RF electrode 512 defines the same angle A1. In other words, the RF electrode 512 may have an ideal frustoconical shape as illustrated in FIG. 6B. In some embodiments, the angle A1 has a value of from 20° to 80°. In some embodiment, the value may be from 20° to 30°, or from 30° to 40°, or from 40° to 50°, or from 50° to 60°, or from 60° to 70°, or from 70° to 80°.

In some embodiments, the spaced revolutions 515-518 are individually arranged such that they can independently vary from the ideal frustoconical shape. In such cases, the angle A1 remains a valid parameter, and these variations represent additional parameters that may be independently tuned, in order to, for example, optimize a spatial uniformity over a wafer of an ICP plasma generated by the RF electrode 512.

For example, some embodiments may have a variation from ideal frustoconical shape as shown in FIG. 6C. FIG. 6C illustrates variations in pitch of individual spaced revolutions, where the pitch of each spaced revolution 515-518 can be defined as the normal (i.e., perpendicular) distance ND from the line L1 to the center of the RF electrode 512 of the spaced revolution 515-518.

In some embodiments, the frustoconical RF electrode 512 has a varying electrode diameter across the length of the coil, such as varying along each spaced revolution 515-518, as shown in FIG. 6D. FIG. 6D illustrates a non-limiting example where the electrode diameter increases across each of four spaced revolutions, from the top spaced revolution 515 to the bottom spaced revolution 518. The RF electrode 512 diameter of some embodiments increases linearly with each successive spaced revolution. In some embodiments, the electrode diameter changes in a non-linear manner with each successive spaced revolution.

In some embodiments, the frustoconical RF electrode 512 has independently varying spacings between each adjacent pair of spaced revolutions 515-518, as shown in FIG. 6E. FIG. 6E illustrates a non-limiting example where the spacing between revolutions decreases going from the top spaced revolution 515 to the bottom spaced revolution 518. In some embodiments, the spacing between the spaced revolutions increases from the top spaced revolution 515 to the bottom spaced revolution 518.

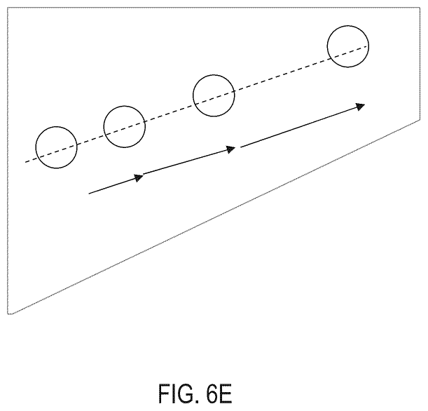

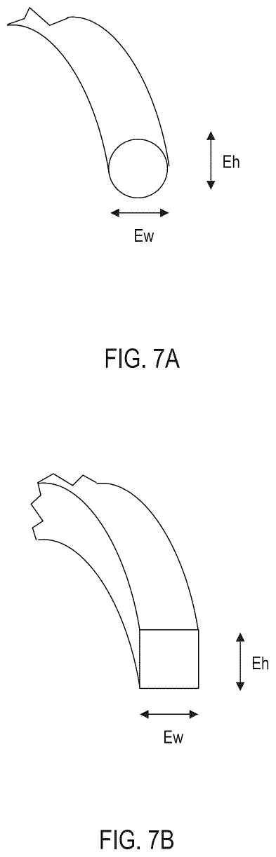

The material forming the RF electrode 512 may have varying dimensions. In some embodiments, the varying dimensions represent additional parameters that can be used to optimize a uniformity of a plasma generated above the substrate support 170 in the processing chamber 100. In some embodiments, the RF electrode 512 has a circular cross-section throughout, as illustrated in FIG. 7A. In some embodiments, the RF electrode 512 has a rectangular cross-section, as illustrated in FIG. 7B. In some embodiments, the rectangular cross-section is a square cross-section. In some embodiments, regardless of whether the RF electrode 512 has a circular, rectangular, or otherwise shaped cross-section, the RF electrode 512 may be formed as either a hollow material or as a solid form. The dimensions of the RF electrode may vary and, in some embodiments, the dimensions may be functions of the input frequencies to the RF electrode 512.

The RF electrode 512 may be made of any suitable material known to the skilled artisan. Exemplary embodiments for the materials of the RF electrode 512 include, but are not limited to, copper, silver, brass, or combinations thereof.

As shown in FIGS. 7A-7B, in some embodiments the RF electrode has an electrode width Ew and an electrode height Eh. In some embodiments, the electrode width Ew is in a range of from 0.1 inches to 0.5 inches and the electrode height Eh is in a range of from 0.01 inches to 0.5 inches. In some embodiments, Eh is in a range from 0.01 inches to 0.03 inches.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A plasma coil assembly comprising:
a ring-shaped body having an inner wall with an inside face and an outside face, a bottom wall with an inside face and an outside face, and an outer wall with an inside face and an outside face, the ring-shaped body having an open top portion;
an RF electrode positioned within the open top portion of the ring-shaped body, the RF electrode having a first end and a second end defining a length of the RF electrode, a thickness and a width, the RF electrode formed in a coil having at least two spaced revolutions with the first end spaced a distance from the outer wall of the ring-shaped body and the second end spaced a distance from the inner wall of the ring-shaped body, the first end closer to a lowest point of the outside face of the bottom wall than the second end;
a first RF electrode connection in electrical contact with the first end of the RF electrode;
a second RF electrode connection in electrical contact with the second end of the RF electrode; and
a dielectric top plate positioned within the open top portion of the ring-shaped body.

2. The plasma coil assembly of claim 1, wherein the coil comprises an outer circular portion connected to an inner circular portion by a straight segment, the outer circular portion concentric with the inner circular portion.

3. The plasma coil assembly of claim 1, wherein the coil comprises an outer circular portion connected to a middle circular portion with an outer straight segment, and the middle circular portion connected to an inner circular portion with an inner straight segment.

4. The plasma coil assembly of claim 1, wherein a diameter of the inner wall of the ring-shaped body is in a range of 250 mm to 500 mm, and a diameter of the outer wall of the ring-shaped body is greater than the diameter of the inner wall of the ring-shaped body and in a range of 450 mm to 650 mm.

5. The plasma coil assembly of claim 1, wherein the first end of the coil has a distance in a range from 0.1 inches to 0.3 inches from the inner face of the outer wall, and the second end of the coil has a distance in a range from 0.1 inches to 0.3 inches from the inner face of the inner wall.

6. The plasma coil assembly of claim 1, wherein the RF electrode has a width in a range of 0.1 inches to 0.5 inches and a height in a range of 0.01 inches to 0.03 inches.

7. The plasma coil assembly of claim 1, wherein a spacing between adjacent revolutions of the at least two spaced revolutions is in a range of 0.1 inches to 3 inches.

8. The plasma coil assembly of claim 1, wherein the ring-shaped body comprises Al₂O₃ or AlN.

9. The plasma coil assembly of claim 1, wherein the dielectric top plate comprises Al₂O₃ or AlN.

10. A semiconductor processing chamber comprising:
a processing chamber body having a bottom, a sidewall and a lid enclosing an interior volume;
a gas distribution assembly connected to the lid of the processing chamber body, the gas distribution assembly configured to provide a flow of gas to the interior volume;
a substrate support within the interior volume, the substrate support having a support body on a support shaft, the support body having a support surface; and
the plasma coil assembly of claim 1 positioned within the interior volume adjacent the lid of the processing chamber, the inner wall of the plasma coil assembly having a diameter greater than a diameter of the support surface.

11. The semiconductor processing chamber of claim 10, wherein the support body comprises a heating element.

12. The semiconductor processing chamber of claim 10, wherein the substrate support comprises a cathode.

13. The semiconductor processing chamber of claim 10, wherein the support shaft is configured to move the substrate support to adjust a distance between the support surface and the lid of the processing chamber body.

14. The semiconductor processing chamber of claim 13, wherein the gas distribution assembly further comprises a gas inlet in the sidewall of the processing chamber body to provide a flow of gas to the interior volume.

15. A method of etching a substrate surface, the method comprising:
exposing the substrate surface to an inductively coupled plasma (ICP), the ICP comprising helium (He); and
applying a bias voltage to the substrate surface,
the ICP being generated at least in part by a plasma coil assembly comprising:
a ring-shaped body having an inner wall with an inside face and an outside face, a bottom wall with an inside face and an outside face, and an outer wall with an inside face and an outside face, the ring-shaped body having an open top portion;
an RF electrode positioned within the open top portion of the ring-shaped body, the RF electrode having a first end and a second end defining a length of the RF electrode, a thickness and a width, the RF electrode formed in a coil having at least two spaced revolutions with the first end spaced a distance from the outer wall of the ring-shaped body and the second end spaced a distance from the inner wall of the ring-shaped body, the first end closer to a lowest point of the outside face of the bottom wall than the second end;
a first RF electrode connection in electrical contact with the first end of the RF electrode;
a second RF electrode connection in electrical contact with the second end of the RF electrode; and
a dielectric top plate positioned within the open top portion of the ring-shaped body.

16. The method of claim 15, wherein the ICP is generated at least in part by a secondary RF coil.
